(19) United States
(12) Patent Application Publication
(10) Pub. No.: US 2026/0123556 A1
(43) Pub. Date: Apr. 30, 2026

(54) SEMICONDUCTOR PACKAGE AND MANUFACTURING METHOD THEREOF

(71) Applicant: Samsung Electronics Co., Ltd., Suwon-si (KR)

(72) Inventor: Hyunseong WOO, Suwon-si (KR)

(73) Assignee: Samsung Electronics Co., Ltd., Suwon-si (KR)

(21) Appl. No.: 19/214,275

(22) Filed: May 21, 2025

(30) Foreign Application Priority Data
Oct. 28, 2024 (KR) 10-2024-0148365

(51) Int. Cl. H01L 23/498; H01L 21/48; H01L 23/00; H01L 23/14; H01L 23/492; H01L 23/538; H01L 25/18; H10B 80/00; H10D 80/30

(52) U.S. Cl. CPC H10W 90/701; H10B 80/00; H10D 80/30; H10W 70/05; H10W 70/26; H10W 70/611; H10W 70/695; H10W 90/00; H10W 90/401; H10W 74/15; H10W 90/724; H10W 90/734

(57) ABSTRACT

Provided is a semiconductor package including a substrate including a mounting region, a first dam surrounding at least a portion of the mounting region, and a second dam spaced apart from the first dam and surrounding the first dam, a sub-semiconductor package on the mounting region of the substrate, conductive bumps between the substrate and the sub-semiconductor package and electrically connecting the substrate and the sub-semiconductor package, and an underfill material filling at least a portion of a space between the substrate and the sub-semiconductor package, and covering the conductive bumps, wherein the first dam and the second dam protrude upward from one surface of the substrate, and an inner wall surface of the first dam includes an inclined surface extending in a direction away from the second dam such that a distance from the second dam to the inclined surface increases as the inner wall surface extends downward.

### CROSS-REFERENCE TO RELATED APPLICATION

This application claims priority to and the benefit of Korean Patent Application No. 10-2024-0148365 filed in the Korean Intellectual Property Office on Oct. 28, 2024, the entire contents of which are incorporated herein by reference.

### BACKGROUND

Some example embodiments relate to a semiconductor package and a manufacturing method thereof.

When a semiconductor package (or semiconductor chip) is mounted on a substrate, an underfill material is filled between the semiconductor package and the substrate to relieve stress caused by differences in coefficients of thermal expansion (CTE) between them and to protect conductive bumps. The underfill material may be dispensed, for example, onto the substrate, and may advance by capillary action in the space between the semiconductor package and the substrate, filling the space therebetween.

### SUMMARY

Some example embodiments provide a semiconductor package and a manufacturing method thereof that may increase the flow rate of an underfill material and prevent (or reduce) void formation.

Alternatively or additionally, some example embodiments provide a semiconductor package and a manufacturing method thereof that may prevent (or reduce) defects due to overflow of an underfill material.

Some example embodiments provide a semiconductor package including a substrate including a mounting region, a first dam surrounding at least a portion of the mounting region, and a second dam spaced apart from the first dam, the second dam surrounding the first dam; a sub-semiconductor package on the mounting region of the substrate; conductive bumps between the substrate and the sub-semiconductor package, the conductive bumps electrically connecting the substrate and the sub-semiconductor package; and an underfill material filling at least a portion of a space between the substrate and the sub-semiconductor package, and the underfill material covering the conductive bumps, wherein the first dam and the second dam protrude upward from one surface of the substrate, and an inner wall surface of the first dam includes an inclined surface extending in a direction away from the second dam such that a distance from the second dam to the inclined surface increases as the inner wall surface extends downward.

Some example embodiments provide a semiconductor package including a first substrate including a mounting region and an insulating layer, a wiring layer embedded in the insulating layer, a pad on the insulating layer electrically connected to the wiring layer, and a protective layer on the insulating layer, the protective layer exposing at least a portion of the pad, a sub-semiconductor package on the mounting region of the first substrate, the sub-semiconductor package including a second substrate, a plurality of semiconductor chips side by side on the second substrate, and an encapsulant covering at least a portion of each semiconductor chip of the plurality semiconductor chips, conductive bumps between the first substrate and the sub-semiconductor package electrically connecting the first substrate and the sub-semiconductor package, and an underfill material filling at least a portion of a space between the first substrate and the sub-semiconductor package, the underfill material covering the conductive bumps, wherein the protective layer includes a first dam protruding upward and surrounding at least a portion of the mounting region, and a second dam spaced apart from the first dam and surrounding the first dam, and an inner wall surface of the first dam includes an inclined surface extending in a direction away from the second dam such that a distance from the second dam to the inclined surface increases as the inner wall surface extends downward.

Some example embodiments provide a manufacturing method of a semiconductor package, including preparing a substrate including an insulating layer, a pad on the insulating layer, and a protective layer on the insulating layer covering the pad, forming, by removing a portion in a thickness direction of each of a first region of the protective layer and a second region spaced apart from the first region to surround the first region, a first dam protruding upward between the first region and the second region and a second dam protruding upward from an outside of the second region, processing the first dam to form an inclined surface on an inner wall surface of the first dam such that a distance from the second dam to the inclined surface increases as the inner wall surface extends downward, disposing a sub-semiconductor package on the first region of the protective layer, and dispensing an underfill material on the inclined surface of the first dam.

Alternatively or additionally, some example embodiments provide a semiconductor package including a substrate including amounting region, a first dam surrounding the at least a portion of the mounting region, and a second dam spaced apart from the first dam, the second surrounding the first dam, and an underfill material on at least a portion of the mounting region, the first dam and the second dam protrude upward from an upper surface of the substrate, and an inner wall surface of the first dam includes an inclined surface extending in a direction away from the second dam such that a distance from the second dam to the inclined surface increases as the inner wall surface extends downward.

In some example embodiments, the semiconductor package further includes a sub-semiconductor package on the mounting region of the substrate, conductive bumps between the substrate and the sub-semiconductor package, the conductive bumps electrically connecting the substrate and the sub-semiconductor package, the underfill material is on at least a portion of the mounting region such that the underfill material fills a space between the substrate and the sub-semiconductor package, the underfill material covering the conductive bumps.

In some example embodiments, the underfill material further covers the first dam and fills at least a portion of a region between the first and the second dam, and the underfill material includes at least one of an epoxy resin or a thermoplastic resin, and further includes at least one of a silica (SiO₂) material, an alumina (Al₂O₃) material, a magnesium oxide (MgO) material, or a carbon nanotube (CNT) material.

Some example embodiments provide a semiconductor package and a manufacturing method thereof that may increase the flow rate of an underfill material and prevent void formation.

Some example embodiments provide a semiconductor package and a manufacturing method thereof that may prevent defects due to overflow of an underfill material.

### BRIEF DESCRIPTION OF THE DRAWINGS

FIG. 1 illustrates a cross-sectional view of a semiconductor package according to some example embodiments.

FIG. 2 illustrates a top view of a semiconductor package according to some example embodiments.

FIG. 3 illustrates a cross-sectional view of a substrate included in a semiconductor package according to some example embodiments.

FIG. 4 illustrates an enlarged view of area “A” of FIG. 3.

FIG. 5 and FIG. 6 illustrate variations of FIG. 4.

FIG. 7 illustrates a cross-sectional view of a semiconductor package according to some example embodiments.

FIG. 8 illustrates a cross-sectional view of a semiconductor package according to some example embodiments.

FIG. 9 to FIG. 17 are drawings for explaining a manufacturing method of a semiconductor package according to some example embodiments.

### DETAILED DESCRIPTION

Inventive concepts will be described more fully hereinafter with reference to the accompanying drawings, in which some example embodiments of inventive concepts are shown. As those skilled in the art would realize, the described example embodiments may be modified in various different ways, all without departing from the spirit or scope of the present inventive concepts.

In order to clearly describe the present inventive concepts, parts or portions that may be irrelevant to the description are omitted, and identical or similar constituent elements throughout the specification may be denoted by the same reference numerals.

Further, in the drawings, the size and thickness of each element may be arbitrarily illustrated for ease of description, and the present inventive concepts are not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

Throughout this specification and the claims that follow, when it is described that an element is “coupled or connected” to another element, the element may be “directly coupled or connected” to the other element or “indirectly coupled or connected” to the other element through a third element. In a similar point of view, this includes not only “physically connected” but also “electrically connected.”

It should be understood that when an element such as a layer, film, region, area or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the words “comprise” and/or “include,” and variations such as “comprises” or “comprising” and/or “includes” or “including,” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Additionally or alternatively, throughout the specification, sequential numbers such as first, second, and the like are used to distinguish a constituent element from other constituent elements that are the same as or similar to it, and are not necessarily used to refer to a specific component. Accordingly, a configuration referred to as a first constituent element in a specific portion of the present specification may be referred to as a second constituent element in other portions of the present specification.

Additionally or alternatively, throughout the specification, singular references to certain constituent elements may include references to a plurality of these constituent elements, unless specifically stated to the contrary. For example, “insulating layer” may be used to mean not only one insulating layer, but also a plurality of insulating layers, such as two, three or more.

Furthermore, throughout the specification, references to directions such as upper surface, upper side, upper portion, lower surface, lower side, and lower portion are described based on the drawings to facilitate explanation and understanding.

It will be understood that elements and/or properties thereof may be recited herein as being “the same” or “equal” as other elements, and it will be further understood that elements and/or properties thereof recited herein as being “the same” as, or “equal” to other elements may be “the same” as, or “equal” to or “substantially the same” as or “substantially equal” to the other elements and/or properties thereof. Elements and/or properties thereof that are “substantially the same” as or “substantially equal” to other elements and/or properties thereof will be understood to include elements and/or properties thereof that are the same as, or equal to the other elements and/or properties thereof within manufacturing tolerances and/or material tolerances. Elements and/or properties thereof that are the same or substantially the same as other elements and/or properties thereof may be structurally the same or substantially the same, functionally the same or substantially the same, and/or compositionally the same or substantially the same.

When the terms “approximately,” “about” or “substantially” are used in this specification in connection with a numerical value, it is intended that the associated numerical value includes a manufacturing or operational tolerance (e.g., +10%) around the stated numerical value. Moreover, when the words “approximately,” “about” and “substantially” are used in connection with geometric shapes, it is intended that precision of the geometric shape is not required but that latitude for the shape is within the scope of the disclosure. Further, regardless of whether numerical values or shapes are modified as “approximately,” “about” or “substantially,” it will be understood that these values and shapes should be construed as including a manufacturing or operational tolerance (e.g., +10%) around the stated numerical values or shapes.

Hereinafter, a semiconductor package and a manufacturing method thereof according to some example embodiments of the present inventive concepts will be described with reference to the drawings.

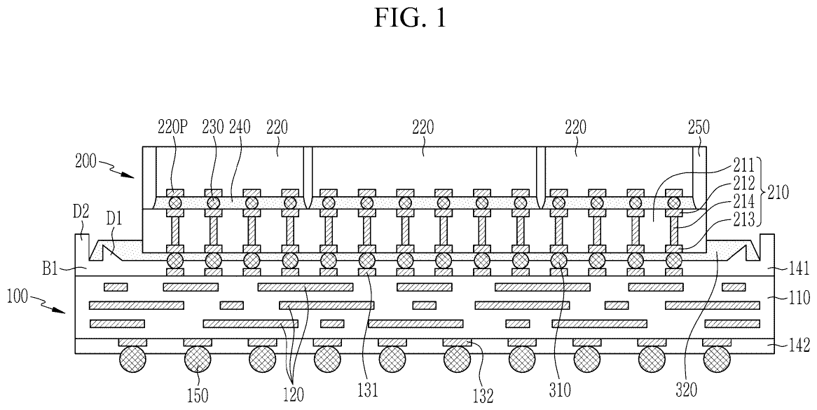

FIG. 1 illustrates a cross-sectional view of a semiconductor package according to some example embodiments.

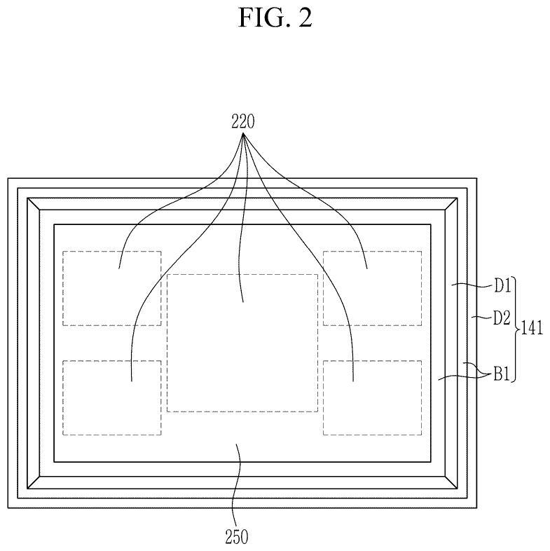

FIG. 2 illustrates a top view of a semiconductor package according to some example embodiments.

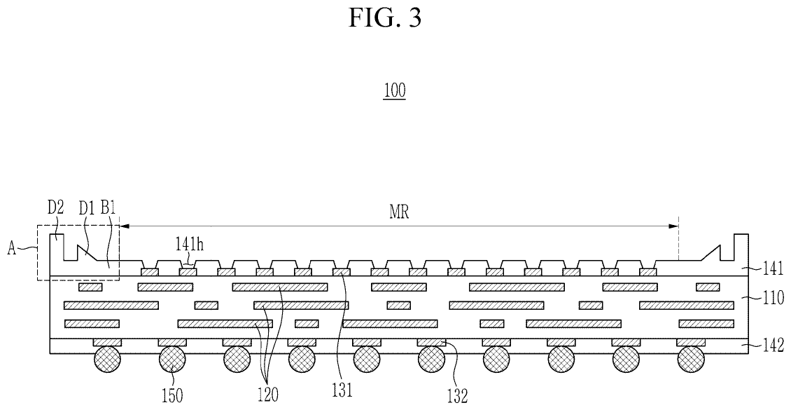

FIG. 3 illustrates a cross-sectional view of a substrate included in a semiconductor package according to some example embodiments.

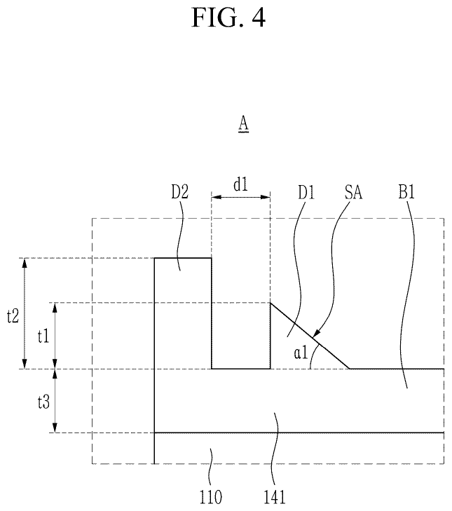

FIG. 4 illustrates an enlarged view of area “A” of FIG. 3.

A semiconductor package may include a first substrate 100, a sub-semiconductor package 200, conductive bumps 310, and an underfill material 320.

The first substrate 100 has a mounting region MR on which the sub-semiconductor package 200 is mounted, and may include an insulating layer 110, a wiring layer 120, pads 131 and 132, protective layers 141 and 142, and a conductive bump 150. The first substrate 100 according to the present inventive concepts may include a first dam D1 to increase the flow rate of the underfill material 320 and prevent (or reduce) void formation, and a second dam D2 to prevent (or reduce) defects due to overflow of the underfill material 320.

The insulating layer 110 may perform an interlayer insulating function. As the material of the insulating layer 110, an insulating material may be used, for example, a thermoplastic resin such as polyimide, a thermosetting resin such as epoxy, FR-4, or the like may be used, but example embodiments are not limited thereto.

The wiring layer 120 may be embedded in the insulating layer 110. The wiring layer 120 may include various wiring patterns, such as a signal pattern that performs a signal transmission function, a power pattern that performs a power transmission function, and a ground pattern that performs a ground function. The number of wiring layers 120 is not particularly limited, and may be greater or less than that shown in the drawings.

The pads 131 and 132 may include a first pad 131 disposed on the upper surface of the insulating layer 110 and a second pad 132 disposed on the lower surface of the insulating layer 110. The first pad 131 and the second pad 132 may be electrically connected to the wiring layer 120, and may electrically connect the first substrate 100 to an external component. For example, the first pad 131 may be electrically connected to the sub-semiconductor package 200, and the second pad 132 may be electrically connected to a substrate (for example, a main board) on which the semiconductor package is mounted.

The wiring layers 120 disposed on different layers, and the wiring layer 120 and the pads 131 and 132 may be connected to each other through vias embedded in the insulating layer 110.

A conductive material may be used as the material for each of the wiring layer 120 and the pads 131 and 132, and for example, aluminum (AI), copper (Cu), gold (Au), platinum (Pt), silver (Ag), tin (Sn), nickel (Ni), chromium (Cr), palladium (Pd), or an alloy of two or more of these may be used, but example embodiments are not limited thereto.

The protective layers 141 and 142 may be disposed on the insulating layer 110 to protect the first substrate 100 from an external environment. The protective layers 141 and 142 may include a first protective layer 141 disposed on the upper surface of the insulating layer 110 and a second protective layer 142 disposed on the lower surface of the insulating layer 110. The material for each of the first protective layer 141 and the second protective layer 142 may be an insulating material such as a solder resist.

The first protective layer 141 and the second protective layer 142 may expose at least a portion of the first pad 131 or the second pad 132 that they cover, respectively. For example, the first protective layer 141 has an opening 141h exposing at least a portion of the first pad 131, and the opening 141h may be filled with a conductive bump 310 when the sub-semiconductor package 200 is mounted. Similarly, the second protective layer 142 has an opening that exposes at least a portion of the second pad 132, and the opening may be filled with a conductive bump 150 formed on the second protective layer 142.

The conductive bump 150 may physically and electrically connect the semiconductor package to an external component. The conductive bump 150 is disposed on the second protective layer 142 and may be connected to the second pad 132 exposed through the second protective layer 142. As a material of the conductive bump 150, a conductive material such as solder may be used.

The first dam D1 and the second dam D2 are disposed around the mounting region MR of the first substrate 100, and may protrude from one surface of the first substrate 100 to an upper side (e.g., the side facing the sub semiconductor package 200 from the first substrate 100). The first dam D1 may surround at least a portion of the mounting region MR, and the second dam D2 may be spaced apart from the first dam D1 to surround the first dam D1.

In some example embodiments, the first dam D1 and the second dam D2 may be formed by the first protective layer 141. In other words, the first dam D1 and the second dam D2 may be some regions included in the first protection layer 141. For example, the first protective layer 141 may include a base portion B1 that performs a surface protective function of the first substrate 100 and a first dam D1 and a second dam D2 that protrude from the base portion B1.

The thickness t3 of the base portion B1 may be about 5 μm to about 15 μm, for example, about 10 μm, but example embodiments are not limited thereto. In some example embodiments, when the thickness t3 of the base portion B1 is too thin (or is thinner than desired), deterioration of insulation performance, weakening of protection function, and/or deterioration of durability may occur. In some example embodiments, when the thickness t3 of the base portion B1 is too thick (or is thicker than desired), poor bonding or reduced bonding strength with the conductive bump 310 of the pad 131 and/or increased thickness of the semiconductor package may occur.

The inner wall surface of the first dam D1 may include an inclined surface SA that becomes farther away from the second dam D2 as it goes to a lower side (e.g., side from the sub semiconductor package 200 toward the first substrate 100). The inclined surface SA may improve the flowability of the underfill material 320 and prevent (or reduce) void formation by increasing the initial flow rate of the underfill material 320 in the dispensing process that advances the underfill material 320 between the first substrate 100 and the sub-semiconductor package 200.

The angle a1 formed by the inclined surface SA and the base portion B1 may be 30° to 60°, for example, about 45°, but example embodiments are not limited thereto. In some example embodiments, when the angle a1 formed by the inclined surface SA and the base portion B1 is too small (or is smaller than desired), the degree of improvement in the initial flow rate of the underfill material 320 may be insignificant, and when the angle a1 formed by the inclined surface SA and the base portion B1 is too large (or is larger than desired), it may be difficult to widely disperse the underfill material 320.

The height t1 of the first dam D1 may be about 5 μm to about 15 μm, for example, about 10 μm, but example embodiments are not limited thereto. In some example embodiments, when the height t1 of the first dam D1 is too low (or is lower than desired), it may be difficult to secure a sufficient inclined surface SA, and thus the degree of improvement in the initial flow rate of the underfill material 320 may be insignificant, and when the height t1 of the first dam D1 is too high (or is higher than desired), it may be difficult to flow the overflowed underfill material 320 to the outside of the first substrate 100. In the present description, the ‘height’ of the dam means the distance from the point where the dams D1 and D2 protrude (for example, the upper surface of the base portion B1) to the highest point of the dam.

Since the second dam D2 is spaced apart from the first dam D1 and surrounds the first dam D1, the overflowed underfill material 320 may be accommodated in a space between the first dam D1 and the second dam D2. Accordingly, it may be possible to prevent (or reduce) defects due to the overflowed underfill material 320, such as the underfill material 320 penetrating into the interface between the first substrate 100 and the sub-semiconductor package 200.

The height t2 of the second dam D2 may be greater than or equal to the height t1 of the first dam D1. In some example embodiments, the height t2 of the second dam D2 may be higher than the height t1 of the first dam D1. The height t2 of the second dam D2 may be from about 5 μm to about 25 μm or from about 10 μm to about 20 μm, for example, about 15 μm, but example embodiments are not limited thereto. In some example embodiments, when the height t2 of the second dam D2 is too low (or is lower than desired), additional overflow through the second dam D2 may occur, and when it is too high (or is higher than desired), process time, cost, and difficulty may increase.

The distance d1 between the first dam D1 and the second dam D2 may be about 5 μm to about 15 μm, for example about 10 μm, but example embodiments are not limited thereto. In some example embodiments, when the distance d1 between the first dam D1 and the second dam D2 is too narrow (or is narrower than desired), it may be difficult to sufficiently accommodate the overflowed underfill material 320, and when it is too wide (or is wider than desired), the efficiency of the additional dispensing process to be described later may be reduced, and an issue of underfilling of the underfill material 320 between the first substrate 100 and the sub-semiconductor package (200) may occur.

In some example embodiments, the first dam D1 and the second dam D2 may include and insulating material. For example, as described above, the first dam D1 and the second dam D2 may be a portion of the protective layer 141, and may be formed of a solder resist like the protective layer 141.

However, as described later, the first dam D1 and the second dam D2 may be formed separately from the protective layer 141, and the first dam D1 and the second dam D2 may include a material different from the protective layer 141, such as a metal. The first dam D1 and the second dam D2 may be formed by etching and laser processing, and may be preferably made of a metal such as copper (Cu) that facilitates etching and laser processing, but example embodiments are not limited thereto.

The sub-semiconductor package 200 may be disposed on the mounting region MR of the first substrate 100.

The sub-semiconductor package 200 may include a second substrate 210, a semiconductor chip 220 (or semiconductor chips 220), a conductive bump 230, an underfill material 240, and an encapsulant 250.

The second substrate 210 may be an interposer substrate.

The second substrate 210 may include, for example, a semiconductor substrate layer 211, a third pad 212, a fourth pad 213, and a through via 214.

The semiconductor substrate layer 211 may include a semiconductor element such as silicon (Si) or a semiconductor compound such as gallium arsenide (GaAs) or indium arsenide (InAs), but example embodiments are not limited thereto.

The third pad 212 and the fourth pad 213 may be disposed on the upper and lower surfaces of the semiconductor substrate layer 211, respectively. Although the third pad 212 and the fourth pad 213 are shown as being embedded in the semiconductor substrate layer 211 in the drawing, the third pad 212 and the fourth pad 213 may protrude from the semiconductor substrate layer 211. The third pad 212 and the fourth pad 213 may electrically connect the second substrate 210 to an external component. For example, the third pad 212 may be electrically connected to the semiconductor chip 220, and the fourth pad 213 may be electrically connected to the first substrate 100.

A conductive material may be used as the material for each of the third pad 212 and the fourth pad 213, and for example, aluminum (AI), copper (Cu), gold (Au), platinum (Pt), silver (Ag), tin (Sn), nickel (Ni), chromium (Cr), palladium (Pd), or an alloy of two or more of these may be used, but example embodiments are not limited thereto.

The through via 214 may penetrate the semiconductor substrate layer 211 and may be electrically connected to the third pad and/or the fourth pad 213. The through via 214 may also be made of a conductive material, and may include, for example, a metal such as copper (Cu), tungsten (W), silver (Ag), nickel (Ni), or an alloy thereof, or doped silicon, but example embodiments are not limited thereto.

A wiring layer and an insulating layer may exist between the semiconductor substrate layer 211 and the third pad 212 and/or between the semiconductor substrate layer 211 and the fourth pad 213.

The semiconductor chips 220 may be disposed side by side on the second substrate 210, but example embodiments are not limited thereto. For example, as necessary, only a single semiconductor chip 220 may be disposed on the second substrate 210, and such an example embodiment is also included in the present inventive concepts.

The semiconductor chips 220 may include at least one of a logic chip and a memory chip. The logic chip may include at least one of an application processor (AP), a microprocessor, a central processing unit (CPU), a graphic processing unit (GPU), a neural processing unit (NPU), an application specific integrated circuit (ASIC), and a system on chip (SoC), but example embodiments are not limited thereto. The memory chip may include at least one of a high bandwidth memory (HBM) chip, a dynamic random access memory (DRAM) chip, a static random access memory (SRAM) chip, a flash memory chip, a read-only memory (ROM) chip, and a magnetic random access memory (MRAM) chip, but example embodiments are not limited thereto.

Each semiconductor chip 220 may include a connection pad 220P. A conductive material may be used as the material for the connection pad 220P, and for example, aluminum (AI), copper (Cu), gold (Au), platinum (Pt), silver (Ag), tin (Sn), chromium (Cr), palladium (Pd), or an alloy of two or more of these may be used, but example embodiments are not limited thereto.

The conductive bump 230 may be disposed between the semiconductor chip 220 and the second substrate 210 to electrically connect them. The conductive bump 230 may connect, for example, the connection pad 220P of the semiconductor chip 220 and the third pad 212 of the second substrate 210. As a material of the conductive bump 230, a conductive material such as solder may be used.

The underfill material 240 may relieve stress caused by a difference in the coefficient of thermal expansion (CTE) between the semiconductor chip 220 and the second substrate 210 and protect the conductive bump 230. The underfill material 240 may fill at least a portion of a space between the semiconductor chip 220 and the second substrate 210 and may cover the conductive bumps 230.

The underfill material 240 may be made of an insulating material, for example, a thermosetting resin such as an epoxy resin, a thermoplastic resin such as polyimide, or the like, but example embodiments are not limited thereto. The underfill material 240 may further include fillers such as silica (SiO₂), alumina (Al₂O₃), magnesium oxide (MgO), and carbon nanotube (CNT) to improve mechanical and thermal stress, but example embodiments are not limited thereto.

The encapsulant 250 may cover at least a portion of each of the semiconductor chips 220. As a material of the encapsulant, an insulating material such as an epoxy molding compound (EMC) may be used. In order to improve the heat dissipation characteristics of the semiconductor package, the upper surface of the semiconductor chip 220 may be exposed on encapsulant 250.

In some example embodiments, the encapsulant 250 may be omitted or may include the second substrate 210 to cover the sub-semiconductor package 200, and this example embodiment is also included in the present inventive concepts.

The conductive bumps 310 may be disposed between the first substrate 100 and the sub-semiconductor package 200 to electrically connect the first substrate 100 and the sub-semiconductor package 200. For example, the conductive bumps 310 may connect the first pad 131 of the first substrate 100 and the fourth pad 213 of the second substrate 210. As a material of the conductive bump 310, a conductive material such as solder may be used.

The underfill material 320 may relieve stress due to a difference in the coefficient of thermal expansion (CTE) between the first substrate 100 and the sub-semiconductor package 200 and protect the conductive bumps 310. The underfill material 320 may fill at least a portion of a space between the first substrate 100 and the sub-semiconductor package 200, and may cover the conductive bumps 310.

The underfill material 320 may further cover the first dam D1 and fill at least a portion of a region between the first dam D1 and the second dam D2. As will be described later, the underfill material 320 may be formed by first dispensing an underfill material on the first dam D1 and second dispensing an underfill material between the first dam D1 and the second dam D2. The underfill material 320 may be uniformly formed by additional dispensing (or may be formed by additional dispensing), and an unfilled issue of the underfill material 320 may be prevented (or reduced) between the first substrate 100 and the sub-semiconductor package 200.

The underfill material 320 may be made of an insulating material, for example, a thermosetting resin such as an epoxy resin, a thermoplastic resin such as polyimide, or the like, but example embodiments are not limited thereto. The underfill material 320 may further include fillers such as silica (SiO₂), alumina (Al₂O₃), magnesium oxide (MgO), carbon nanotube (CNT) to improve mechanical and thermal stress, but example embodiments are not limited thereto.

In some example embodiments, when a semiconductor package (or semiconductor chip) is mounted on a substrate, an underfill material is filled between the semiconductor package and the substrate to relieve stress caused by differences in coefficients of thermal expansion (CTE) between them and to protect conductive bumps. The underfill material may be dispensed, for example, onto the substrate, and may advance by capillary action in the space between the semiconductor package and the substrate, filling the space therebetween.

In some example embodiments, when the dispensed underfill material does not have sufficient flow rate, voids may occur in the underfill material. Additionally or alternatively, when the underfill material overflows, a defect in the semiconductor package may occur due to the underfill material penetrating between the substrate and the semiconductor package.

According to some example embodiments, by introducing the first dam D1 to the first substrate 100, the flow rate of the underfill material 320 may be increased and void formation may be prevented (or reduced), and by introducing the second dam D2, defects due to overflow of the underfill material 320 may be prevented (or reduced). The effect of introducing the first dam D1 and the second dam D2 may be particularly noticeable when applied to a large-area semiconductor package such as a 2.5D semiconductor package that requires improvement in the flow rate of the underfill material 320 (or for which improvement in the flow rate of the underfill material 320 may be beneficial).

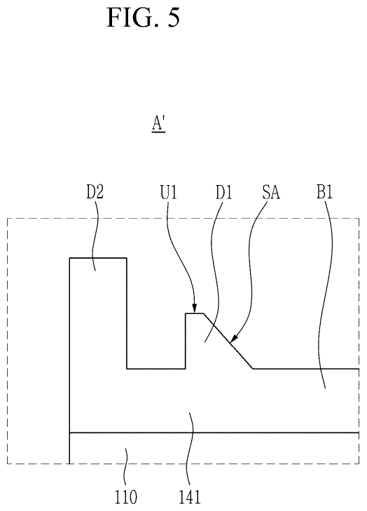

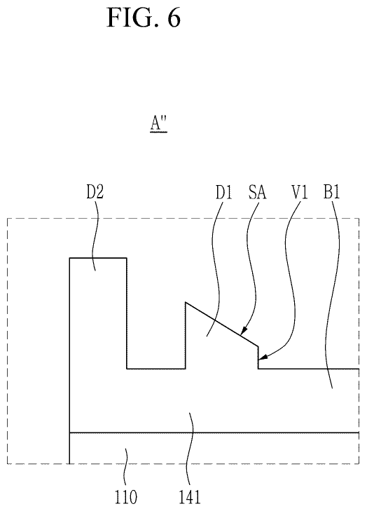

FIG. 5 and FIG. 6 illustrate variations of FIG. 4.

Referring to FIG. 5, the first dam D1 may have an upper surface U1 connected to the inclined surface SA. The upper surface U1 of the first dam D1 may be substantially flat without being inclined.

Referring to FIG. 6, the inner wall surface of the first dam D1 may be connected to the inclined surface SA, and may further include a substantially vertical inclined section V1.

As will described later, the first dam D1 can be formed by tilting a pre-processed dam having a substantially quadrangular shape with a laser, and depending on (or based on) the laser processing position, a portion of the upper surface and/or the inner wall surface of the pre-processed dam may remain in the first dam D1.

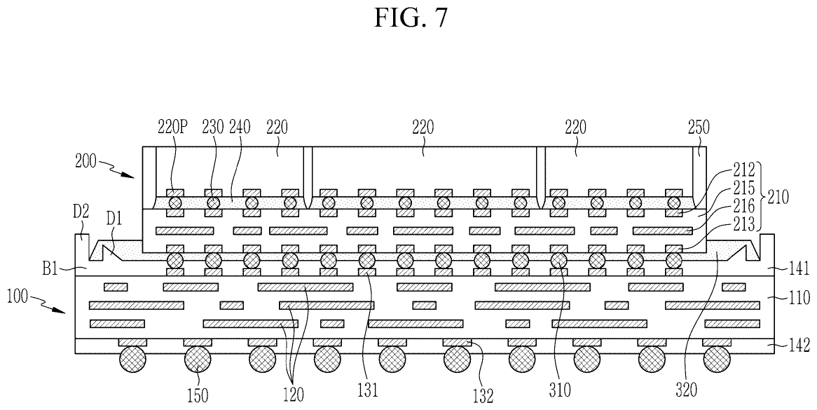

FIG. 7 illustrates a cross-sectional view of a semiconductor package according to some example embodiments.

The second substrate 210 may replace the semiconductor substrate layer 211 to include an organic insulating layer 215. A wiring layer 216 may be embedded inside the organic insulating layer 215. As the material of the organic insulating layer 215, an insulating material may be used, for example, a thermoplastic resin such as polyimide, a thermosetting resin such as epoxy, FR-4, or the like may be used, but example embodiments are not limited thereto.

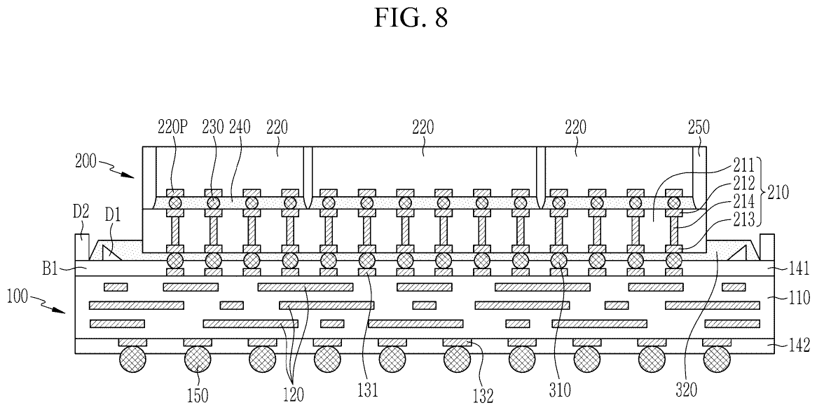

FIG. 8 illustrates a cross-sectional view of a semiconductor package according to some example embodiments.

The first dam D1 and the second dam D2 may be formed separately from the first protective layer 141, and may be formed on the first protective layer 141. For example, the first protective layer 141 may include only the base portion B1, and the first dam D1 and the second dam D2 may be disposed on the first protective layer 141. Therefore, the first dam D1 and the second dam D2 may have a boundary with the first protective layer 141.

The first dam D1 and the second dam D2 may be made of the same material as the first protective layer 141, or may be made of a material different from that of the first protective layer 141. For example, the first protective layer 141 may be made of an insulating material, and the first dam D1 and the second dam D2 may be made of an insulating material or a metal.

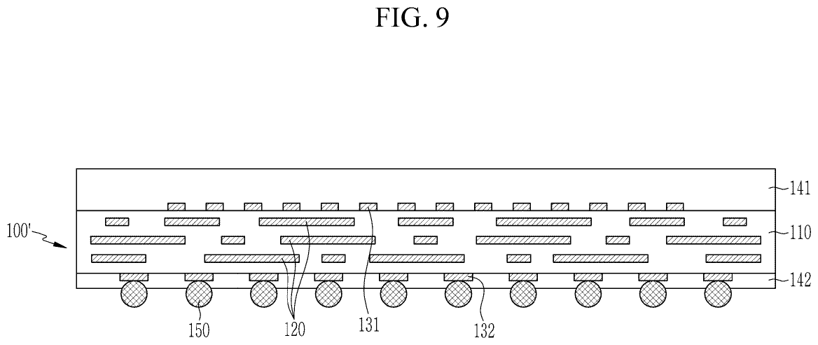

FIG. 9 to FIG. 17 are drawings for explaining a manufacturing method of a semiconductor package according to some example embodiments.

First, referring to FIG. 9, a first substrate 100′ before processing, which may include the insulating layer 110, the wiring layer 120, the pads 131 and 132, the protective layers 141 and 142, and the conductive bump 150, is prepared. In the first substrate 100′ before processing, the first protective layer 141 may have a thickness greater than that of the second protective layer 142.

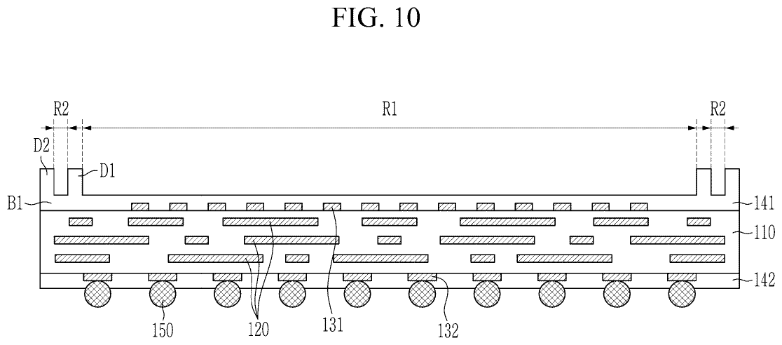

Next, referring to FIG. 10, a portion in the thickness direction of each of the first region R1 of the first protective layer 141 and the second region R2 spaced apart from the first region R1 to surround the first region R1 is removed to form the first dam D1 and the second dam D2 in the first protective layer 141. Each of the first region R1 and the second region R2 may have a groove shape surrounded by each of the first dam D1 and the second dam D2. The first dam D1 and the second dam D2 are unremoved regions of the first protective layer 141, and may protrude upward relatively compared to the first region R1 and the second region R2 to have a dam shape. By removing the first region R1 and the second region R2, the first dam D1 may be disposed between the first region R1 and the second region R2, and the second dam D2 may be disposed outside the second region R2.

A portion of each of the first region R1 and the second region R2 may be removed by etching (e.g., dry etching or wet etching). Etching has the advantage of being able to process relatively large areas of the first region R1 and second region R2 at low cost. However, example embodiments are not limited thereto, and the first region R1 and the second region R2 may be removed through other methods such as laser processing or mechanical processing.

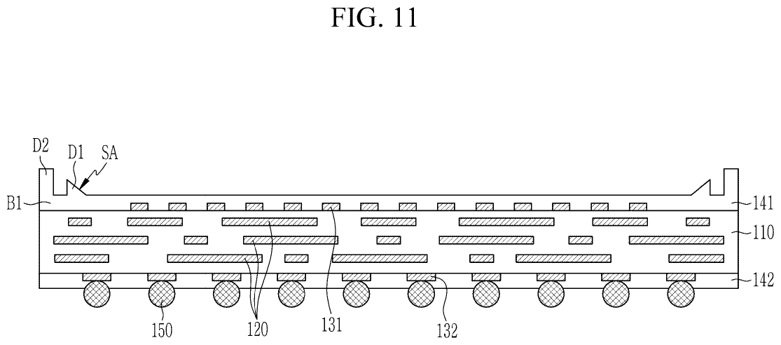

Next, referring to FIG. 11, the first dam D1 is processed to form the inclined surface SA on the inner wall surface of the first dam D1, the inclined surface SA extending in a direction away from the second dam D2 such that the distance from the second dam D2 to the inclined surface SA increases as the inner wall surface goes (or extends) downward. In some example embodiments, when the inclined surface SA is formed, the first dam D1 may be processed with a laser beam. For example, the inclined surface SA may be formed by obliquely irradiating a laser light source to the first dam D1 and tilting the first dam D1.

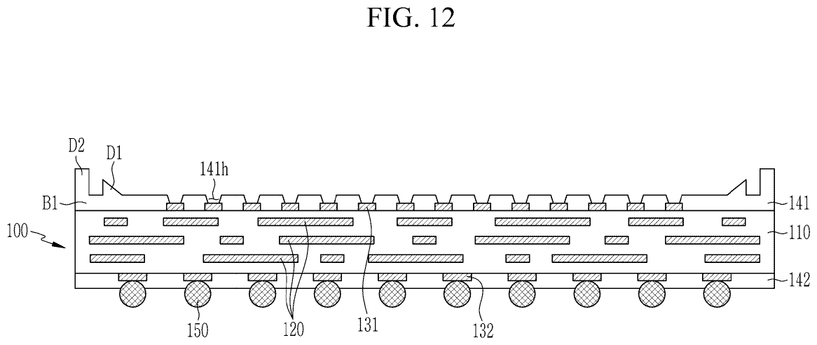

Next, referring to FIG. 12, the opening 141h is formed to expose the first pad 131 in the first protective layer 141. The method of forming the opening 141h is not particularly limited, and, for example, laser processing may be used.

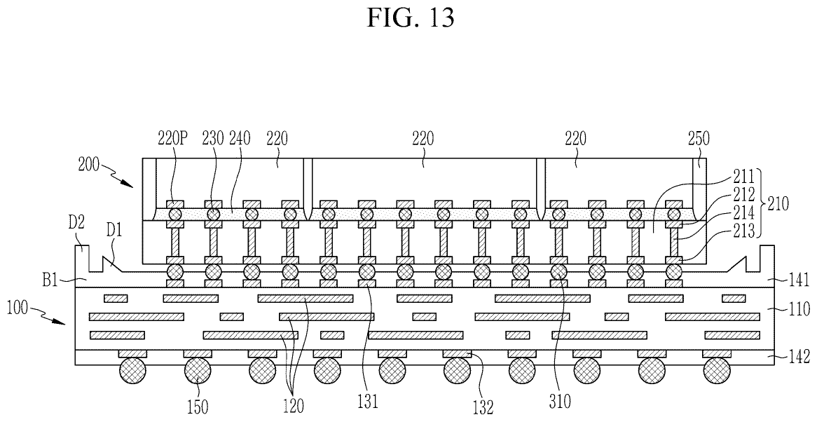

Next, referring to FIG. 13, the sub-semiconductor package 200 is disposed on the first substrate 100 (e.g., the first region R1 of the protective layer 141 of the first substrate 100). The sub-semiconductor package 200 may be disposed on the first substrate 100 by, for example, attaching the conductive bump 310 on the sub-semiconductor package 200 and bonding the conductive bump 310 on the first substrate 100. The first region R1 may be substantially wider than the mounting region MR where the sub-semiconductor package 200 is disposed.

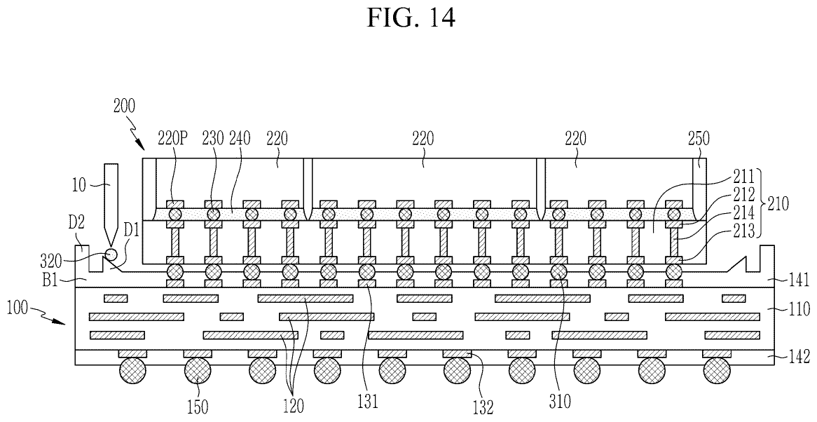

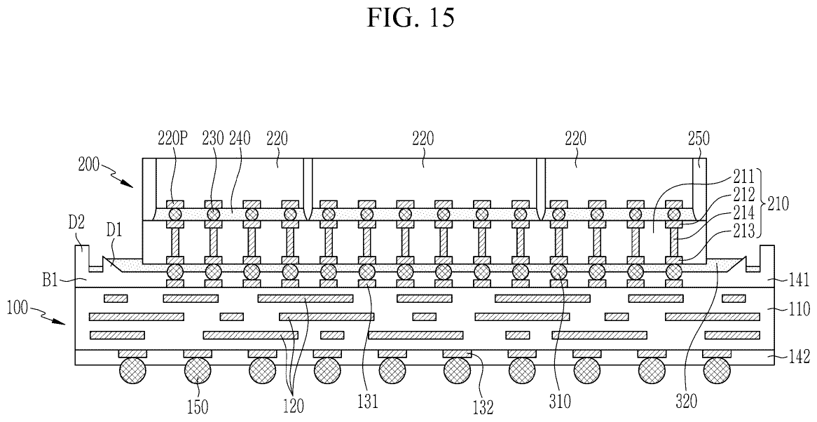

Next, referring to FIG. 14 and FIG. 15, the underfill material 320 is dispensed onto the inclined surface SA of the first dam D1. The underfill material 320 may be dispensed using a known dispenser 10. In some example embodiments, the underfill material 320 may be dispensed multiple times on a plurality of points of the inclined surfaces SA of the first dam D1. The first dispensed underfill material 320 may flow between the first substrate 100 and the sub-semiconductor package 200 to fill at least a portion of the space therebetween. Additionally or alternatively, when the underfill material 320 overflows, the overflowed underfill material 320 may flow into the space between the first dam D1 and the second dam D2.

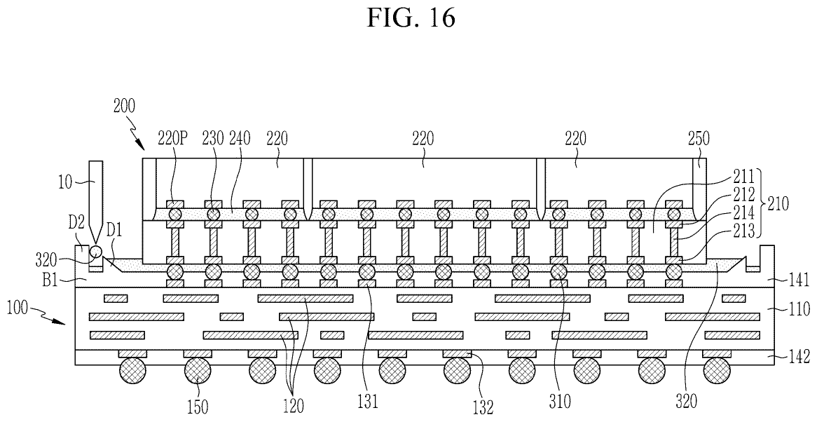

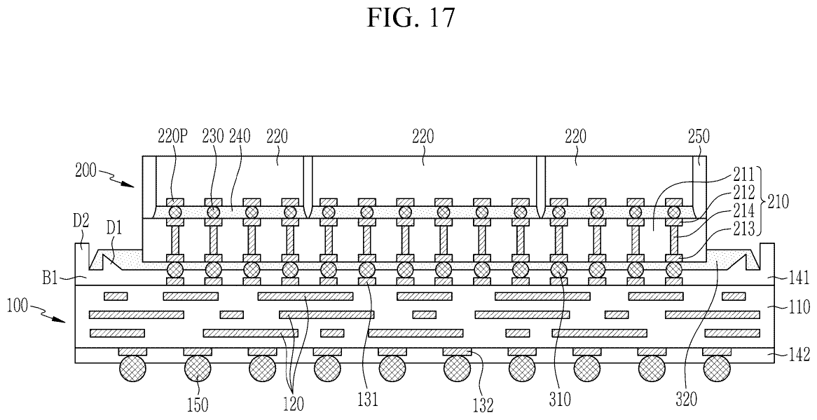

Next, referring to FIG. 16 and FIG. 17, the underfill material 320 is additionally dispensed on the second region R2 of the protective layer 141. The secondarily dispensed underfill material 320 may fill the space between the first dam D1 and the second dam D2, and fill the unfilled space between the first substrate 100 and the sub-semiconductor package 200 beyond the first dam D1. Additionally or alternatively, the secondarily dispensed underfill material 320 may provide uniform formation of the underfill material 320 in the final semiconductor package structure.

After dispensing the underfill material 320, a process of curing the underfill material 320 may be performed. The curing temperature of the underfill material 320 may be appropriately selected depending on (or based on) the material of the underfill material 320.

While this description has been described in connection with some example embodiments, it is to be understood that the present inventive concepts are not limited to the example embodiments, but, on the contrary, is intended to cover various modifications and equivalent arrangements included within the spirit and scope of the appended claims.

In addition, the example embodiments disclosed herein are not independent of each other, and may be implemented in combination with each other unless they are specifically contradictory. Accordingly, example embodiments in which some example embodiments are combined should also be considered to be included in the present inventive concepts.

What is claimed is:

1. A semiconductor package comprising:
a substrate including a mounting region, a first dam surrounding at least a portion of the mounting region, and a second dam spaced apart from the first dam, the second dam surrounding the first dam;
a sub-semiconductor package on the mounting region of the substrate;
conductive bumps between the substrate and the sub-semiconductor package, the conductive bumps electrically connecting the substrate and the sub-semiconductor package; and
an underfill material filling at least a portion of a space between the substrate and the sub-semiconductor package, the underfill material covering the conductive bumps,
wherein the first dam and the second dam protrude upward from one surface of the substrate, and
an inner wall surface of the first dam includes an inclined surface extending in a direction away from the second dam such that a distance from the second dam to the inclined surface increases as the inner wall surface extends downward.

2. The semiconductor package of claim 1, wherein
a height of the second dam is greater than a height of the first dam.

3. The semiconductor package of claim 1, wherein
a height of the first dam is 5 μm to 15 μm.

4. The semiconductor package of claim 1, wherein
a height of the second dam is 5 μm to 25 μm.

5. The semiconductor package of claim 1, wherein
a distance between the first dam and the second dam is 5 μm to 15 μm.

6. The semiconductor package of claim 1, wherein
the underfill material further covers the first dam and fills at least a portion of a region between the first dam and the second dam.

7. The semiconductor package of claim 1, wherein
the first dam and the second dam include an insulating material.

8. The semiconductor package of claim 1, wherein
the first dam and the second dam include metal.

9. The semiconductor package of claim 1, wherein
the substrate further includes an insulating layer, a pad on the insulating layer, and a protective layer on the insulating layer, the protective layer exposing at least a portion of the pad,
the protective layer includes the first dam, the second dam, and a base portion, and
the first dam and the second dam protrude from the base portion.

10. The semiconductor package of claim 9, wherein
an angle between the inclined surface of the first dam and the base portion is 30° to 60°.

11. The semiconductor package of claim 9, wherein
a thickness of the base portion is 5 μm to 15 μm.

12. The semiconductor package of claim 1, wherein
the substrate further includes an insulating layer, a pad on the insulating layer, and a protective layer on the insulating layer, the protective layer exposing at least a portion of the pad, and
the first dam and the second dam are on the protective layer.

13. A semiconductor package comprising:
a first substrate including a mounting region and an insulating layer;
a wiring layer embedded in the insulating layer;
a pad on the insulating layer electrically connected to the wiring layer; and
a protective layer on the insulating layer, the protective layer exposing at least a portion of the pad;
a sub-semiconductor package on the mounting region of the first substrate, the sub-semiconductor package including a second substrate, a plurality of semiconductor chips side by side on the second substrate, and an encapsulant covering at least a portion of each semiconductor chip of the plurality of semiconductor chips;
conductive bumps between the first substrate and the sub-semiconductor package electrically connecting the first substrate and the sub-semiconductor package; and
an underfill material filling at least a portion of a space between the first substrate and the sub-semiconductor package, the underfill material covering the conductive bumps;
wherein the protective layer includes a first dam protruding upward and surrounding at least a portion of the mounting region, and a second dam spaced apart from the first dam and surrounding the first dam, and
an inner wall surface of the first dam includes an inclined surface extending in a direction away from the second dam such that a distance from the second dam to the inclined surface increases as the inner wall surface extends downward.

14. The semiconductor package of claim 13, wherein
the second substrate includes a semiconductor substrate layer.

15. The semiconductor package of claim 13, wherein
the second substrate includes an organic insulating layer.

16. The semiconductor package of claim 13, wherein
the plurality of semiconductor chips include at least one of a logic chip and a memory chip.

17. A method of manufacturing a semiconductor package, comprising:
preparing a substrate including an insulating layer, a pad on the insulating layer, and a protective layer on the insulating layer covering the pad;
forming, by removing a portion in a thickness direction of each of a first region of the protective layer and a second region spaced apart from the first region to surround the first region, a first dam protruding upward between the first region and the second region and a second dam protruding upward from outside of the second region;
processing the first dam to form an inclined surface on an inner wall surface of the first dam such that a distance from the second dam to the inclined surface increases as the inner wall surface extends downward;
disposing a sub-semiconductor package on the first region of the protective layer; and
dispensing an underfill material on the inclined surface of the first dam.

18. The method of claim 17, further comprising
additionally dispensing the underfill material on the second region of the protective layer.

19. The method of claim 17, wherein
in the forming of the first dam and the second dam, a portion of each of the first region and the second region is removed by etching.

20. The method of claim 17, wherein
in the forming of the inclined surface, the first dam is processed with a laser beam.
